(19) United States
(12) Patent Application Publication
(10) Pub. No.: US 2013/0119352 A1
(43) Pub. Date: May 16, 2013

(54) MULTI-STRUCTURE CATHODE FOR FLEXIBLE ORGANIC LIGHT EMITTING DIODE (OLED) DEVICE AND METHOD OF MAKING SAME

(71) Applicant: Deeder Mohammad Aurongzeb, Mayfield Heights, OH (US)

(72) Inventor: Deeder Mohammad Aurongzeb, Mayfield Heights, OH (US)

(21) Appl. No.: 13/295,505

(22) Filed: Nov. 14, 2011

(51) Int. Cl. H01L 51/52; H01L 51/56

(52) U.S. Cl. 257/40; 438/26; 257/E51.018; 257/E51.001

(57) ABSTRACT

Described is a method for making a flexible OLED lighting device. The method includes forming a plurality of OLED elements on a flexible planar substrate, each of the OLED elements including a continuous respective anode layer formed over the substrate. One or more organic light emitting materials is formed over the anode layer; a continuous cathode layer having a first thickness is formed over the light emitting materials; and a discontinuous cathode layer having a second thickness is formed over the continuous cathode layer. An encapsulating protective cover may be formed over the cathode layers. Each of the OLED elements defines a bendable, continuous light region on the substrate, wherein the substrate and combination of OLED elements define an OLED device that more effectively dissipates heat and has an active light area that is bendable.

### FIELD OF THE INVENTION

The field of the invention relates generally to organic light emitting diode (OLED) devices, and more particularly to a cathode structure in a flexible OLED device and method of making same.

### BACKGROUND OF THE INVENTION

Organic electroluminescent devices, such as organic light emitting diodes (OLEDs), have been widely used for display applications, and the use of such devices in general lighting applications is gaining acceptance. An OLED device includes one or more organic light emitting layers disposed between two electrodes, e.g., a cathode and an anode, carried on a substrate. An encapsulating cover is disposed over the cathode. The OLED device may be “top-emitting”, wherein the produced light is emitted through the cover, or “bottom-emitting” wherein the produced light is emitted through the substrate. The organic light emitting layer emits light upon application of a voltage across the anode and cathode, whereby electrons are directly injected into the organic layer from the cathode, and holes are directly injected into the organic layer from the anode. The electrons and the holes travel through the organic layer until they recombine at a luminescent center. This recombination process results in the emission of a photon, i.e., light.

Large area OLED devices typically combine many individual OLED elements on a single substrate. Use of large area OLED devices as a light source in lighting fixtures is gaining acceptance in the lighting industry. OLED devices, which typically have an Al/Ag cathode structure and a thickness of less than 200 nm, are an efficient, high-brightness light source, but are not without certain inherent drawbacks. The devices generate significant internal heat, which can be dissipated in larger area devices, but also operate in high temperature environments. Prolonged exposure to high temperatures may induce localized degradation of the devices (e.g., de-lamination of the light-emitting layers), often resulting in color shift and/or highly visible dark spots in the illumination field. High temperatures also result in an overall decrease in brightness of the device, thus limiting the useful life of the devices.

One approach to improving heat management and cooling an OLED device is set forth in published U.S. Pat. Application No. 2005/0285518, which proposes a “thick” cathode configuration. The cathode has a continuous thickness of greater than 500 nm over and between the light emitting elements, and is preferably greater than 10 microns. The '518 publication also proposes to add a heat conductive layer to the cathode cover, with this layer preferably having a thickness of at least 100 microns. The premise of the '518 publication is that a cathode below 500 nm thickness will not provide sufficient heat conductivity, and that a “thick” cathode and thermally conductive cover are needed.

Flexible OLED devices are formed with flexible substrates of metal foils, plastic films, and the like, and offer certain advantages. These devices are lightweight, durable, and impact resistant. Their use in lighting applications and displays for cell phones, PDAs, portable computers, and so forth, is gaining wider acceptance. The flexible OLED devices are, however, subject to the same high temperature issues discussed above, in addition to the increased stresses in the light emitting materials resulting from bending or twisting the OLED devices. The solution proposed by the '518 publication discussed above is not suitable for flexible OLED devices in that the increased thickness cathode and protective cover configuration only adds to the bending stresses and likely would induce cracking and delamination in the underlying layers.

Therefore, a need exists in the industry for an improved cathode structure and cathode protection layer particularly suited for flexible OLED devices that operate in high temperature environments.

### BRIEF DESCRIPTION OF THE INVENTION

Aspects and advantages of the invention will be set forth in part in the following description, or may be obvious from the description, or may be learned through practice of the invention.

For example, embodiments of the invention provide an OLED lighting device that is flexible or bendable, and which is capable of operating in high temperatures, e.g., above about 40 C. Since embodiments of such OLED devices are flexible, they may be mounted to any manner of curved support surface, such as a pole, curved wall or platform, a curved frame member, any type of non-flat fixture, and so forth. Accordingly, such flexible OLED lighting devices are significantly more versatile than rigid OLED lighting devices. Flexible OLED devices in accordance with embodiments of the present invention have a unique combination of characteristics that provide for heat management of the devices without unduly inhibiting or limiting flexibility of the devices. Characteristics of the OLED lighting devices are tailored to the intended bend configuration and active light area of the devices so as to provide sufficient heat management without unnecessarily limiting or inhibiting flexibility.

In accordance with aspects of the invention, a method for making a flexible OLED lighting device includes forming a plurality of OLED elements on a flexible planar substrate. Each of the OLED elements includes a continuous respective anode layer formed over the substrate. One or more organic light emitting materials are formed over the anode layer. A cathode layer is formed over the light emitting materials, and an encapsulating protective cover is formed over the cathode layer. The method of making the device includes forming a continuous cathode layer on the one or more organic light emitting materials so that the continuous cathode layer defines a first thickness and then forming on the continuous cathode layer a discontinuous cathode layer; wherein the discontinuous cathode layer defines a second thickness: and the second thickness of the discontinuous cathode layer varies as a function of the coordinates of the discontinuous cathode layer in a plane parallel to the plane defined by the upper surface of the substrate. The discontinuous cathode layer can be implemented as a plurality of discrete columns of cathode material separated by gaps or by imposing a smoothly continuous height variation on the amount of cathode material deposited on the continuous cathode layer, or by a combination of the foregoing. Thus, the thickness of the cathode layer is not constant over the area defined by each of the OLED elements. Certain regions of the cathode layer can attain thicknesses of as much as ten microns. Each of the OLED elements defines a bendable, continuous light region on the substrate, wherein the substrate and combination of OLED elements have an active light area of 50 cm² or greater, define an OLED device that more effectively dissipates heat and has an active light area that is bendable.

In a particular embodiment, at least one mask is used to form the discontinuous cathode layer in the form of a plurality of columns of cathode material, each column being spaced apart from each other column by a plurality of gaps. In such embodiments, the second thickness desirably defines a height of each column above the continuous cathode layer, and the height of each column desirably measures more than twice the first thickness of the continuous cathode layer. In an exemplary embodiment, the at least one mask desirably defines a plurality of openings, and each opening desirably is spaced apart from the nearest neighboring opening by a distance of at least one micron. In another exemplary embodiment, the height of at least some of the columns of cathode material desirably is at least ten microns. In a further exemplary embodiment, the first thickness of the continuous cathode layer desirably is less than or equal to 200 nanometers (nm) and desirably is no more than about 100 nm.

In an additional embodiment, the discontinuous cathode layer is formed by varying the second thickness as a smoothly continuous function of the coordinates of the second thickness in a plane parallel to the plane of the upper surface of the substrate so as to impose a smoothly continuous variation of the height of cathode material that is disposed above the continuous cathode layer. In a particular embodiment, a rotating mask desirably can be used to vary the thickness of cathode material forming the discontinuous cathode layer in a continuous manner from zero to ten microns. In another embodiment, a series of masks desirably can be used to vary the thickness of cathode material forming the discontinuous cathode layer in a continuous manner from zero to ten microns.

In an exemplary embodiment of the method and the resulting OLED elements, the height variation that defines the thickness of the cathode material that is deposited above the continuous cathode layer desirably results in thicker amounts of the cathode material at a plurality of the outer peripheral regions of the resulting OLED elements than the thickness of cathode material that is deposited onto the more interior regions of the continuous cathode layer. In a particular embodiment of the method and the resulting OLED elements, cathode material desirably is deposited above a plurality of the outer peripheral regions of the continuous cathode layer to a height of at least ten microns above the height of the continuous cathode layer. In a further embodiment of the method and the resulting OLED elements, the height of cathode material deposited above a contiguous region of the continuous cathode layer disposed away from the plurality of outer peripheral regions of the continuous cathode layer, is desirably less than or equal to 200 nanometers. In another exemplary embodiment of the method of the method and the resulting OLED elements, the height of the cathode material that is deposited above a plurality of the outer peripheral regions of the continuous cathode layer desirably is shorter than the height of the cathode material that is deposited above the more interior regions of the continuous cathode layer.

Embodiments of the present invention also encompass any manner of flexible OLED lighting device made in accordance with the methods discussed herein. An exemplary OLED device may include a flexible planar substrate, and a plurality of OLED elements formed on the substrate, with the substrate and OLED elements having an active light area which may be 50 cm² or greater in certain embodiments. The cathode layer includes a first thickness of a continuous cathode layer formed on the organic layer and includes a discontinuous cathode layer formed on the continuous cathode layer. The discontinuous cathode layer formed on the continuous cathode layer defines a second thickness that varies as a function of the coordinates of the discontinuous cathode layer in a plane parallel to the plane defined by the upper surface of the substrate. In an exemplary embodiment, the continuous cathode layer desirably has a thickness between 100 nm and 200 nm.

In a particular embodiment of the flexible OLED device, the discontinuous cathode layer desirably defines a plurality of columns of cathode material formed on the continuous cathode layer, each column being spaced apart from each other column and defining a height above the continuous cathode layer, wherein the height of each column desirably measures more than twice the first thickness of the continuous cathode layer. In another embodiment of the flexible OLED device, each of a plurality of the columns of the discontinuous cathode layer desirably is spaced apart from its nearest neighboring column by a distance of at least one micron. In a further embodiment of the flexible OLED device, the height of each of a plurality of the columns desirably is at least ten microns.

In still another embodiment of the flexible OLED device, the height of cathode material deposited above a plurality of the outer peripheral regions of the continuous cathode layer is desirably at least ten microns above the height of the continuous cathode layer. In yet another embodiment of the flexible OLED device, the height of cathode material deposited above a contiguous region of the continuous cathode layer disposed away from the plurality of outer peripheral regions of the continuous cathode layer, is less than or equal to 200 nanometers. In an additional embodiment of the flexible OLED device, the height of cathode material that is disposed above the continuous cathode layer desirably is shorter above a plurality of the outer peripheral regions of the continuous cathode layer.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 schematically illustrates from a top plan view, a partially completed embodiment of an exemplary flexible OLED lighting device;

FIG. 2 schematically illustrates from an elevated perspective view, the partially completed embodiment of FIG. 1 in a bent configuration;

FIG. 3 is a cross sectional view taken in the direction of the arrows designated 3-3 in FIG. 1;

FIG. 4 is a perspective view of the OLED lighting device of FIGS. 1, 2, 3 and 5 in a first bent configuration;

FIG. 5 is an elevated perspective view of an alternative embodiment of a partially completed exemplary flexible OLED lighting device;

FIG. 6 schematically illustrates from an elevated perspective view, an embodiment of a method of making the cathode layer of an alternative exemplary flexible OLED lighting device;

FIG. 7 is an elevated perspective view of another alternative embodiment of a partially completed exemplary flexible OLED lighting device;

FIG. 8 is an elevated perspective view of still another alternative embodiment of a partially completed exemplary flexible OLED lighting device;

FIG. 9 schematically illustrates from an elevated perspective view, a step in an embodiment of an exemplary method for making the cathode layer of the embodiment shown in FIG. 7;

FIG. 10 schematically illustrates from an elevated perspective view, a step in an embodiment of an exemplary method for making the cathode layer of the embodiment shown in FIG. 8;

FIG. 11 is a perspective view of the flexible OLED lighting device of FIG. 8 in a first bent configuration;

FIG. 12 is a perspective view of the flexible OLED lighting device of FIG. 7 in a first bend configuration;

FIG. 13 is a perspective view of an alternative configuration of the partially completed flexible OLED lighting device of FIG. 5;

FIG. 14 schematically illustrates a further alternative embodiment of an exemplary flexible OLED lighting device;

FIG. 15 schematically illustrates still another alternative embodiment of an exemplary flexible OLED lighting device;

FIG. 16 schematically illustrates yet a further alternative embodiment of an exemplary flexible OLED lighting device; and

FIG. 17 schematically illustrates an additional alternative embodiment of an exemplary flexible OLED lighting device:

FIG. 18 is a flowchart illustrating an exemplary method of forming a discontinuous cathode layer on a continuous cathode layer or a flexible OLED lighting device; and

FIG. 19 schematically illustrates an embodiment of an exemplary method for making an exemplary flexible OLED lighting device.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents. The same identifying numerals are used in the drawings to identify like elements throughout the Figures.

It is to be understood that the ranges and limits mentioned herein include all ranges located within the prescribed limits (i.e., sub-ranges and sub-limits). For instance, a range from 100 to 200 also includes sub-ranges, such as, but not limited to from 110 to 150, 170 to 190, 153 to 162, and 145.3 to 149.6. Further, a limit of up to 7 also includes a sub-limit of up to 5, up to 3; and up to 4.5, as well as sub-ranges within the limit, such as, but not limited to, sub-ranges from about 1 to 5 and from 3.2 to 6.5.

The term “organic” is used herein to refer to a class of chemical compounds that are comprised of carbon atoms. For example, an “organic polymer” is a polymer that includes carbon atoms in the polymer backbone, but may also include other atoms either in the polymer backbone and/or in side chains extending from the polymer backbone (e.g., oxygen, nitrogen, sulfur, etc.).

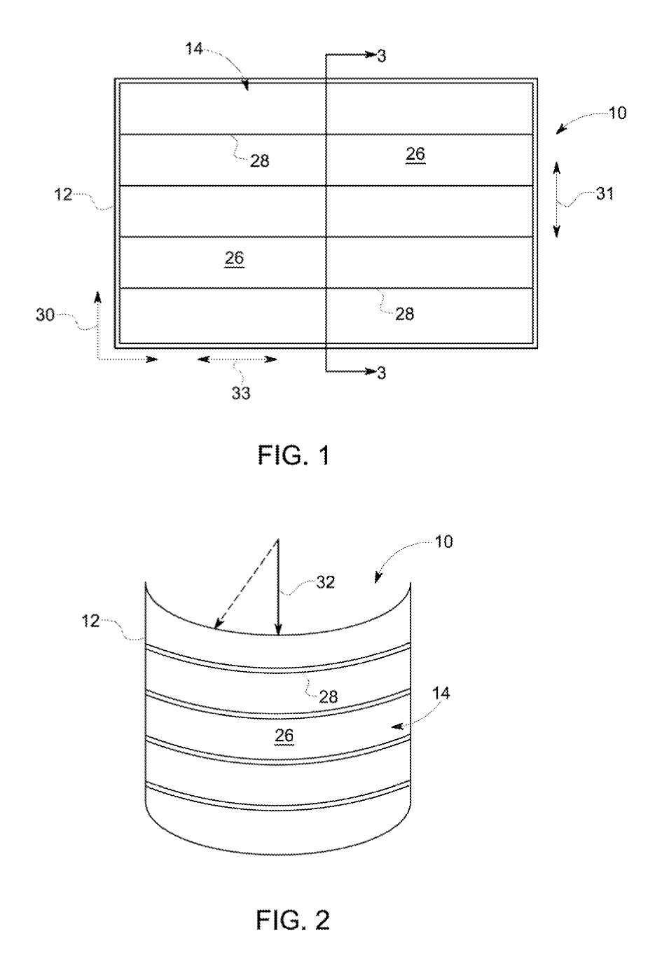

FIG. 1 schematically illustrates from a top plane view, an embodiment of an exemplary OLED lighting device 10 illustrated as a generally flat, planar member having a width 31 and a length 33. It should be appreciated that the rectangular shape of the OLED device 10 in FIG. 1 is for illustrative purposes only, and that an OLED device 10 in accordance with aspects of the invention may have any desired shape, size, or other configuration.

The overall OLED device 10 in FIG. 1 includes a plurality of individual OLED elements 14 configured on a suitable substrate 12, which is a pliable, bendable member, such as, but not limited to, a metal or plastic sheet member. In the depicted embodiment, the OLED elements 14 are disposed lengthwise across the substrate 12, and each OLED element 14 defines a generally continuous, unbroken light region 26. The OLED elements 14 may be separated by spacings 28, which may be scribe lines 28 that are formed after the deposition process wherein the various material layers deposited on the substrate 12 are separated by laser or other scribing techniques to define the individual OLED elements 14, as is well known in the art. The overall OLED device 10 has an active light area 30 that is defined essentially by the combined surface area of the OLED elements 14, particularly the light regions 26. In this regard, the overall OLED device 10 is particularly well-suited as a wide-area light source that may be incorporated into any manner of light fixture.

FIG. 2 schematically depicts an OLED device 10 of the type in FIG. 1 in one possible bend configuration. The substrate 12 is bent into a configuration with a bending radius 32. It should be readily appreciated from FIG. 2 that the bending radius 32 decreases as the degree of bend increases. In other words, less pronounced bends have a larger bending radius 32 as compared to tighter bends. It also should be appreciated that each OLED device 10 has a maximum bend configuration (minimum bending radius 32) beyond which the device 10 should not be bent if irreparable damage (including complete failure of the device 10) is to be avoided.

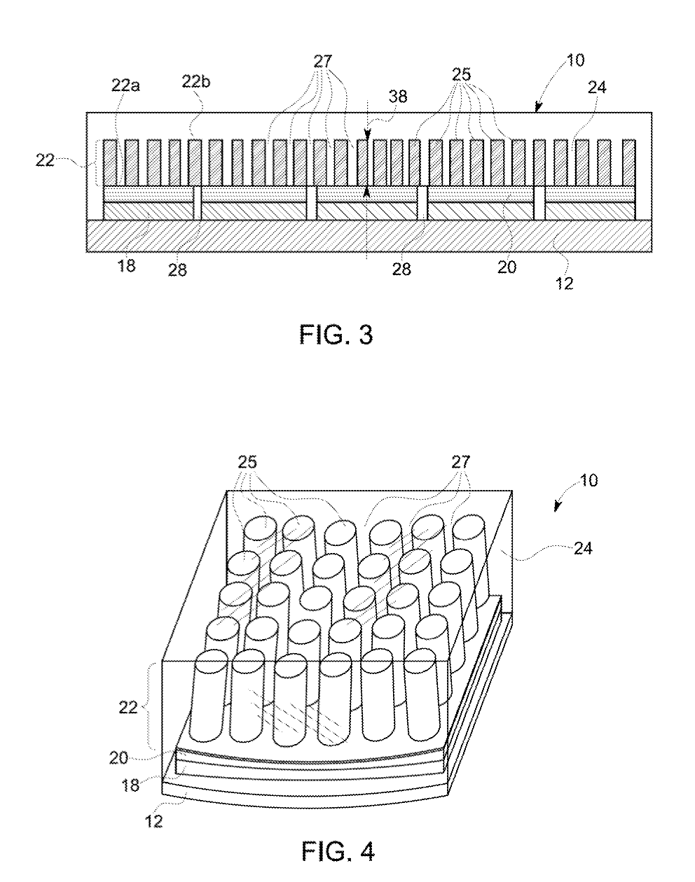

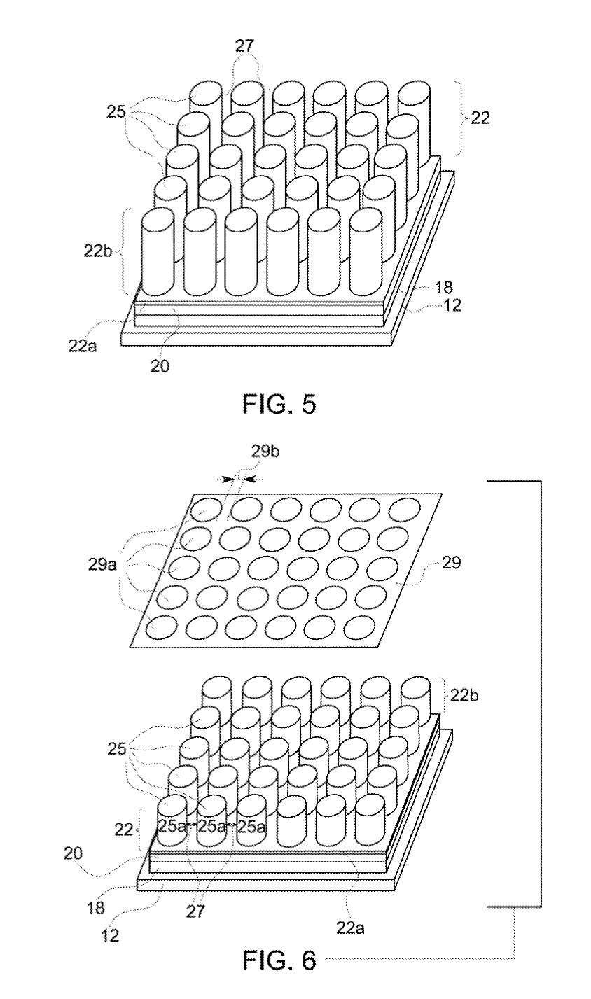

FIG. 3 is a cross-sectional view of an exemplary top-emitting device 10 wherein light is emitted through the cathode layer 22 and an adjacent protective cover layer 24, which is formed from a transparent or translucent material. It should be appreciated that an OLED device 10 in accordance with aspects of the invention also may be a bottom-emitting OLED device 10, wherein light is emitted through the substrate layer 12. FIG. 4 schematically represents an orthogonal view of the device 10 of FIG. 3, but shown in a slightly bended configuration such that the bottom surface of the substrate 12 bows outwardly in a convex shape. FIG. 5 schematically represents an orthogonal view of portions of the device 10 of FIG. 3 absent the protective cover layer 24, but shown in an unbended configuration such that the bottom surface of the substrate 12 lies flat.

As schematically shown in FIGS. 3, 4 and 5 for example, a first electrode layer 18 is deposited on the planar upper surface of the flexible substrate 12. In the exemplary method schematically represented in FIG. 19, this step is designated by the square labeled 51. For reference, the electrode layer 18 is designated as the anode layer. For a bottom-emitting device, the anode layer 18 is transmissive of light and is at least translucent and desirably is transparent. The anode layer 18 generally comprises a material having a low work function value such that a relatively small voltage causes emission of electrons from the anode 18. The anode layer 18 may comprise, for example, indium tin oxide (ITO), tin oxide, nickel, or gold. The anode layer 18 may be formed by conventional deposition techniques, such as vapor deposition, sputtering, and so forth to provide a continuous anode layer formed on the substrate.

As schematically shown in FIGS. 3, 4 and 5 for example, a layer of organic light emitting materials 20 is deposited on the anode layer 18. In the exemplary method schematically represented in FIG. 19, this step is designated by the square labeled 52. One or more layers of organic light emitting materials can form the organic layer 20. A variety of organic light emitting material layers are known and can be used in conjunction with exemplary embodiments of the invention. According to the embodiment shown in FIGS. 3, 4 and 5, the organic layer 20 comprises a single layer, and may include, for example, a conjugated polymer which is luminescent, a hole-transporting polymer doped with electron transport molecules and a luminescent material, or an inert polymer doped with hole transporting molecules and a luminescent material. The organic light emitting layer 20 also may comprise an amorphous film of luminescent small organic molecules, which can be doped with other luminescent molecules. According to other embodiments of the invention, the organic light emitting layer 20 may include two or more sub-layers which carry out the functions of hole injection, hole transport; electron injection, electron transport; and luminescence. Only the luminescent layer is required for a functioning device. However, the additional sub-layers generally increase the efficiency with which holes and electrons recombine to produce light. Thus, the organic light emitting layer 20 can comprise sub-layers including, for example, a hole injection sub-layer, a hole transport sub-layer, a luminescent sub-layer, and an electron injection sub-layer. Also one or more sub-layers may comprise a material that achieves two or more functions such as hole injection, hole transport, electron injection, electron transport, and luminescence.

As schematically shown in FIGS. 3, 4 and 5 for example, a cathode layer 22 is deposited on the organic light emitting layer 20 by any suitable deposition technique. The cathode layer 22 may comprise, for example, calcium or a metal such as gold, indium, manganese, tin, lead, aluminum, silver, magnesium, or a magnesium/silver alloy. Alternatively, the cathode can be made of two layers to enhance electron injection. Examples include a thin inner layer of lithium fluoride (LiF) followed by a thicker outer layer of aluminum or silver, or a thin inner layer of calcium followed by a thicker outer layer of aluminum or silver.

As schematically shown in FIGS. 3, 4 and 5 for example, the cathode layer 22 is deposited so as to include a continuous cathode layer 22a formed on the one or more organic light emitting materials so that the continuous cathode layer 22a defines a first thickness, which desirably measures in a range of 100 nm to 200 nm. In the exemplary method schematically represented in FIG. 19, this step is designated by the square labeled 53.

As schematically shown in FIGS. 3, 4, and 5 for example, the cathode layer 22 includes additional cathode material that is deposited on the continuous cathode layer 22a to form a discontinuous cathode layer 22b so that the discontinuous cathode layer 22b defines at least a second thickness of cathode material formed above the continuous cathode layer 22a. In the exemplary method schematically represented in FIG. 19, this step is designated by the square labeled 54. The second thickness of the discontinuous cathode layer 22b desirably varies as a function of the coordinates of the discontinuous cathode layer 22b in a virtual plane that is disposed parallel to the plane defined by the upper surface of the substrate 12. The discontinuous cathode layer 22b can be implemented in a number of different configurations to form different embodiments of the OLED lighting device 10. As explained more fully below, exemplary ways of forming these different configurations are schematically shown in FIGS. 6, 9 and 10.

In one exemplary embodiment of the discontinuous cathode layer 22b shown in FIGS. 3, 4 and 5 for example, a plurality of columns 25 or islands 25 of cathode material is formed on the continuous cathode layer 22a. As schematically shown in FIGS. 3, 4 and 5 for example, each column 25 of cathode material in the discontinuous cathode layer 22b desirably is spaced apart from each other column 25 in the discontinuous cathode layer 22b. Accordingly, in this embodiment of an implementation of the discontinuous cathode layer 22b, the discontinuous cathode layer 22b is rendered discontinuous by a plurality of gaps 27 separating each column 25 of cathode material from each other column 25 of cathode material. As schematically shown in FIGS. 3, 4 and 5 for example, each column 25 of a plurality of the columns 25 desirably is spaced apart from its nearest neighboring column 25 by a distance of at least one micron, which distance defines the gap 27 that exists between adjacent columns 25 in the discontinuous cathode layer 22b. These gaps 27 desirably will be formed on the order of the finest resolution with which the existing technology can deposit the cathode material. Currently, that limit of resolution is on the order of one micron.

As schematically shown in FIGS. 3, 4 and 5 for example, each column 25 of cathode material in the discontinuous cathode layer 22b desirably defines a height above the continuous cathode layer 22a, and that height is the second thickness of the discontinuous cathode layer 22b. As schematically shown in FIGS. 3, 4 and 5 for example, the height of each column 25 of cathode material in the discontinuous cathode layer 22b desirably measures more than twice the magnitude of the first thickness of the continuous cathode layer 22a. Desirably, the height of each column 25 in the plurality of the columns 25 forming the discontinuous cathode layer 22b is as long as at least ten microns. As schematically indicated in FIG. 3, in embodiments in which the thickness (or height) of the continuous cathode layer 22a measures in a range of 100 nm to 200 nm and the height of the discontinuous layer cathode layer 22b measures up to ten microns, the overall height 38 of the cathode layer 22 will exceed ten microns, and yet the OLED lighting device 10 will retain its desired flexibility.

As schematically shown in FIG. 6 for example, at least one mask 29 desirably is used to form the discontinuous cathode layer 22b in the form of a plurality of columns 25 of cathode material. In this exemplary embodiment of the flexible OLED lighting device 10, the discontinuous cathode layer 22b is segmented to provide discrete islands 25 of cathode material above a thin, continuous cathode layer 22a. A thin, continuous cathode layer 22a of about 100 nanometers of cathode material desirably is deposited on top of the luminescent organic layer 20. Then a mask 29 can be placed over the thin continuous layer 22a of cathode material. The at least one mask 29 desirably defines a plurality of openings 29a, and additional cathode material is deposited through the openings 29a in the mask 29 until attaining a discontinuous cathode layer 22b having a thickness of up to ten microns above the first thickness of 100 nanometers of cathode material that defines the continuous cathode layer 22a.

The mask 29 imposes an island grid over the thin continuous layer 22a of cathode material so that there are produced discrete islands 25 of very thick columns 25 of cathode material forming the discontinuous cathode layer 22b. The gaps 27 between the islands 25 can be uniform or non-uniform in size, as the desired bending configuration of the desired flexible OILED lighting device 10 demands. Thus, the pattern or grid of the placements of the islands 25 can be uniform or varied, as the desired bending configuration of the desired flexible OLED lighting device 10 demands.

Each opening 29a in the mask desirably is spaced apart from the nearest neighboring opening 29a by a distance that is on the order of the finest resolution with which the existing technology can fashion a mask capable of controlling the deposition of the cathode material. Currently, this limit of resolution is on the order of one micron, but when finer resolution masks become available, they also can be used. As schematically shown in FIG. 6 for example, the edge surfaces 25a of each island 25 are separated from the edge surfaces 25a of each immediately adjacent island 25 by a gap 27 defining a distance that depends on the resolution of the mask that is available. Thus, as schematically shown in FIGS. 3.4 and 5 for example, each cathode island 25 can be formed as a cylindrically shaped column having a diameter of one micron and separated from each adjacent cathode island 25 by one micron. Accordingly, as schematically shown in FIGS. 3, 4 and 5 for example, each column 25 becomes spaced apart from each other nearest column 25 by a plurality of gaps 27 that attain distances correlating with the spaces 29b separating the openings 29a in the mask 29. Moreover, cathode islands 25 can be formed with cross sectional shapes other than the circular shapes depicted in FIGS. 3, 4, 5 and 6. For example, columns having square cross sectional shapes (or shaped as any other polygon) can be formed by suitable deposition techniques.

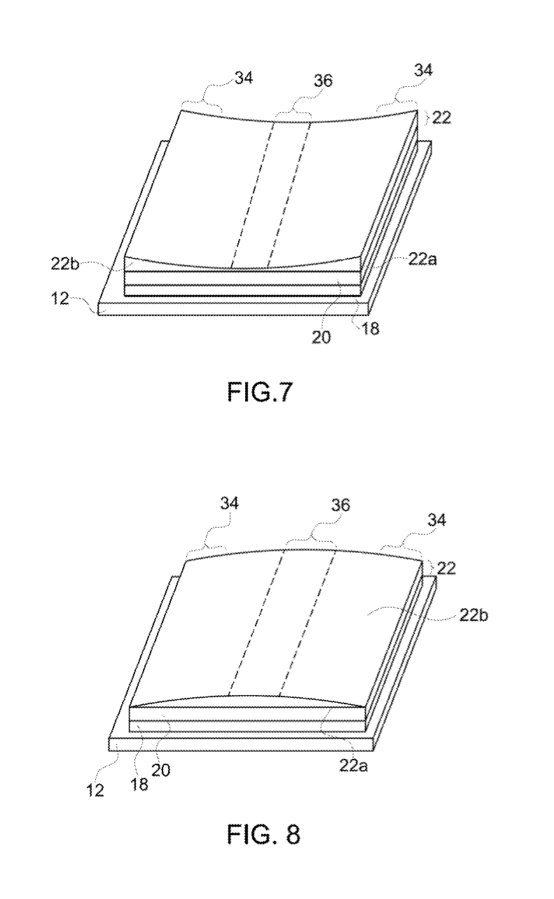

In another exemplary embodiment of the discontinuous cathode layer 22b, the second thickness that defines the discontinuous cathode layer 22b varies as a smoothly continuous function of the coordinates of the second thickness in a virtual plane that lies parallel to the plane of the upper surface of the substrate 12. Accordingly, in this implementation of the discontinuous cathode layer 22b, the discontinuous cathode layer 22b is rendered discontinuous by the imposition of a smoothly continuous variation of the height of cathode material that is disposed above the continuous cathode layer 22a. Indeed, the implementations of the discontinuous cathode layer 22b as depicted in FIGS. 3, 4, 5 and 6 also can be thought of as imposing a variation in the height of cathode material that is disposed above the continuous cathode layer 22a, but the variation takes the form of a pattern of zero height of cathode material where there is no island 25 above the continuous cathode layer 22a and some definite height of cathode material above where there is an island 25 of cathode material built on top of the continuous cathode layer 22a. In some sense, the embodiment of FIGS. 3, 4, 5 and 6 also can be thought of as the digital implementation in which the variation in the height of the cathode material that is a function of position on the continuous cathode layer 22a, is mathematically a step function. While the embodiment of FIGS. 7, 8, 16 and 17 can be thought of as the analog implementation in which the variation of height as a function of position on the continuous cathode layer 22a, provides a height profile that is mathematically a smoothly continuous curve that is a function of position along any line on the continuous cathode layer 22a.

In the embodiments of the cathode layer schematically depicted in FIGS. 7 and 8 for example, the deposition of the cathode material is varied gradually so that, depending upon the application for the OLED element, cathode material at some regions of the OLED will be at a maximum of about 10 microns in depth while at other regions of the OLED the cathode material will be at less than half of that maximum depth of cathode material. This is accomplished by depositing a depth of cathode material evenly for about a depth of in the range of 100 nanometers to 200 nanometers to form the continuous cathode layer 22a, and then masking some locations while a second deposition of the cathode material is provided to form the discontinuous cathode layer 22b. Thus, where the mask blocked the deposition of the cathode material, the depth of the cathode material will be less than the depth of cathode material in places where the mask allowed the cathode material to be deposited. Different masks can be used successively to gradually build up a cathode layer that has a height profile (or depth profile) as a function of the position on the underlying layer of organic material.

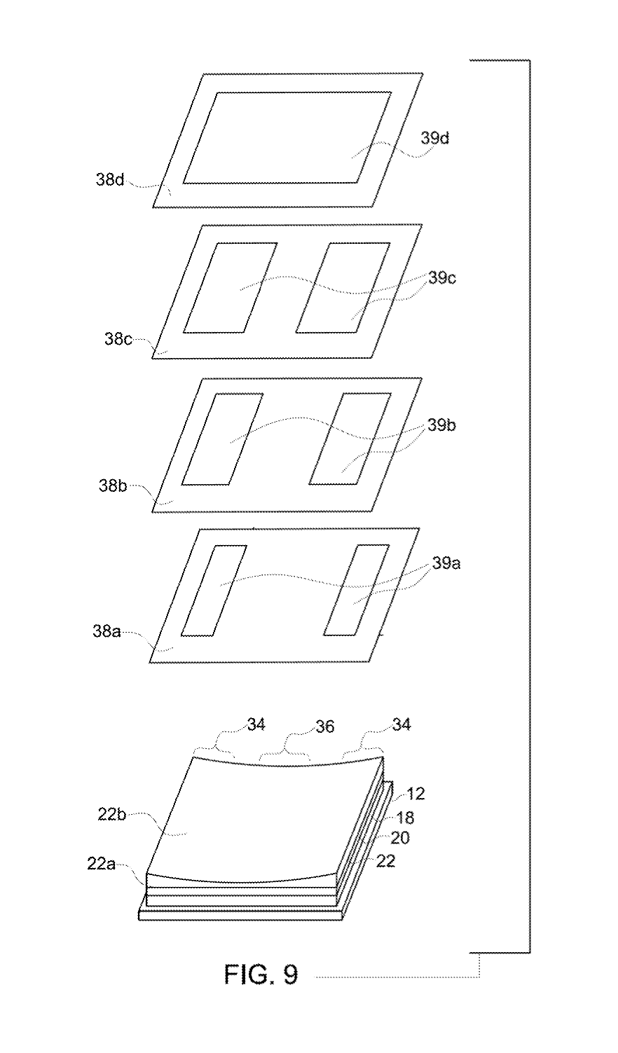

As schematically shown in FIG. 9 for example, to produce a cathode layer 22 as schematically shown in FIG. 7 for example, at least one mask 38a desirably is used to form the discontinuous cathode layer 22b in the form of a variation in the height of cathode material deposited on the continuous cathode layer 22a. Desirably, a rotating mask can be used to generate deposition of cathode material so that the variation in the height of cathode material in the discontinuous cathode layer 22b desirably is taller above a plurality of the outer peripheral regions 34 of the continuous cathode layer 22a and shorter in the regions 36 that are more distant from the outer peripheral regions 34 of the continuous cathode layer 22a. Alternatively, as schematically shown in FIG. 9 for example, a succession of masks 38a, 38b, 38c, 38d of ever increasingly sized respective openings 39a, 39b, 39c, 39d toward the outer periphery of the masks 38a, 38b, 38c, 38d can be used to generate deposition of cathode material so that the height variation of cathode material in the discontinuous cathode layer 22b desirably is higher above a plurality of the outer peripheral regions 34 of the continuous cathode layer 22a and shorter in the regions 36 that are more distant from the outer peripheral regions 34 of the continuous cathode layer 22a.

In exemplary embodiments configured as schematically depicted in FIG. 7 for example, the cathode layer 22 at the central portion 36 of the OLED is at a minimum depth of about 200 nanometers, while the height of the cathode layer 22 at the peripheral edges 34 of the OLED are at a maximum depth of about between 5 and 10 microns. In each case, the thickness profile of the cathode layer 22 gradually increases as a function of the distance from the center 36 of the OLED.

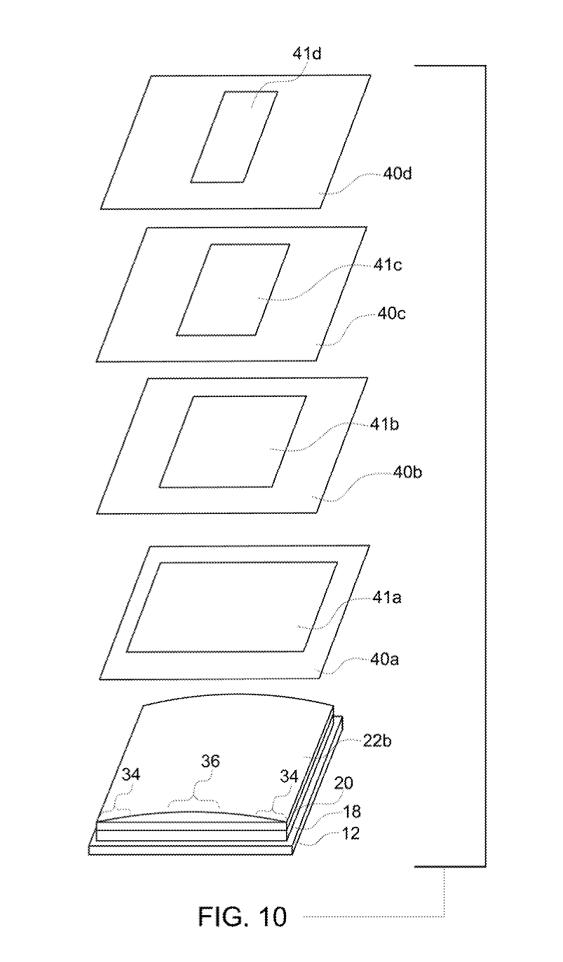

As schematically shown in FIG. 10 for example, to produce a cathode layer 22 as schematically shown in FIG. 8 for example, at least one mask 40a desirably is used to form the discontinuous cathode layer 22b in the form of a variation in the height of cathode material deposited above the continuous cathode layer 22a. Desirably, a rotating mask can be used to generate deposition of cathode material so that the height of cathode material in the discontinuous cathode layer 22b desirably is shorter above a plurality of the outer peripheral regions 34 of the continuous cathode layer 22a and higher in the regions 36 that are more distant from the outer peripheral regions of the continuous cathode layer 22a. Alternatively, as schematically shown in FIG. 10 for example, a succession of masks 40a, 40b, 40c, 40d of ever decreasingly sized respective openings 41a, 41b, 41c, 41d toward the inner sections of the masks 40a, 40b, 40c. 40d can be used to generate deposition of cathode material so that the height of cathode material in the discontinuous cathode layer 22b desirably is shorter above a plurality of the outer peripheral regions 34 of the continuous cathode layer 22a and taller in the regions 36 that are more distant from the outer peripheral regions 34 of the continuous cathode layer 22a.

In exemplary embodiments configured as schematically depicted in FIG. 8 for example, the cathode layer 22 at the central portion 36 of the OLED is at a maximum depth of about between 5 and 10 microns, while the height of the cathode layer 22 at the peripheral edges 34 of the OLED are at a minimum depth of about 100 nanometers to 200 nanometers. In each case, the thickness profile of the cathode layer 22 gradually decreases as a function of the distance from the center 36 of the OLED.

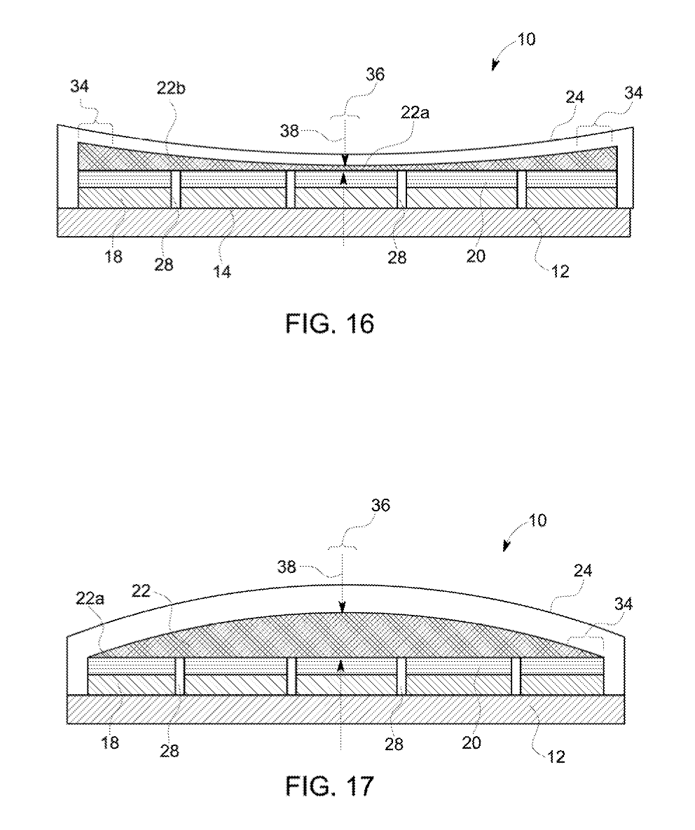

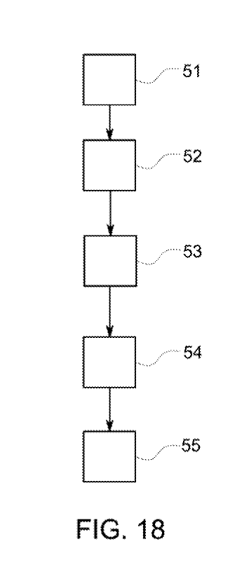

FIG. 16 schematically represents a cross sectional view similar to the view of FIG. 3 but taken of the embodiment depicted partially in FIG. 7 in which the protective cover layer 24 is absent similar to the view of FIG. 5. As schematically shown in FIGS. 7 and 16 for example, the height variation of cathode material in the outer peripheral regions 34 of the discontinuous cathode layer 22b desirably is taller than the height of cathode material disposed away from the outer peripheral regions of the underlying continuous cathode layer 22a of cathode material. The cathode material that is deposited to form the outer peripheral regions 34 of the discontinuous cathode layer 22b above a plurality of the outer peripheral regions of the continuous cathode layer 22a desirably measures up to a height of at least ten microns above the first thickness of the continuous cathode layer 22a. As schematically shown in FIG. 7 for example, the variation in the height of cathode material in the outer peripheral regions 34 of the discontinuous cathode layer 22b desirably is such that the height of cathode material deposited to form a contiguous region 36 of the discontinuous cathode layer 22b disposed away from the plurality of outer peripheral regions 34 of the discontinuous cathode layer 22b, is less than or equal to 200 nanometers.

FIG. 17 schematically represents a cross sectional view similar to the view of FIG. 3 but taken of the embodiment depicted partially in FIG. 8 in which the protective cover layer 24 is absent similar to the view of FIG. 5. In an alternative embodiment schematically shown in FIGS. 8 and 17 for example, the variation in the height of cathode material in the discontinuous cathode layer 22b desirably is shorter above a plurality of the outer peripheral regions 34 of the discontinuous cathode layer 22b deposited above the outer peripheral regions of the continuous cathode layer 22a than the height variation of the cathode material deposited to form a contiguous region 36 of the discontinuous cathode layer 22b disposed away from the plurality of outer peripheral regions 34 in the discontinuous cathode layer 22b.

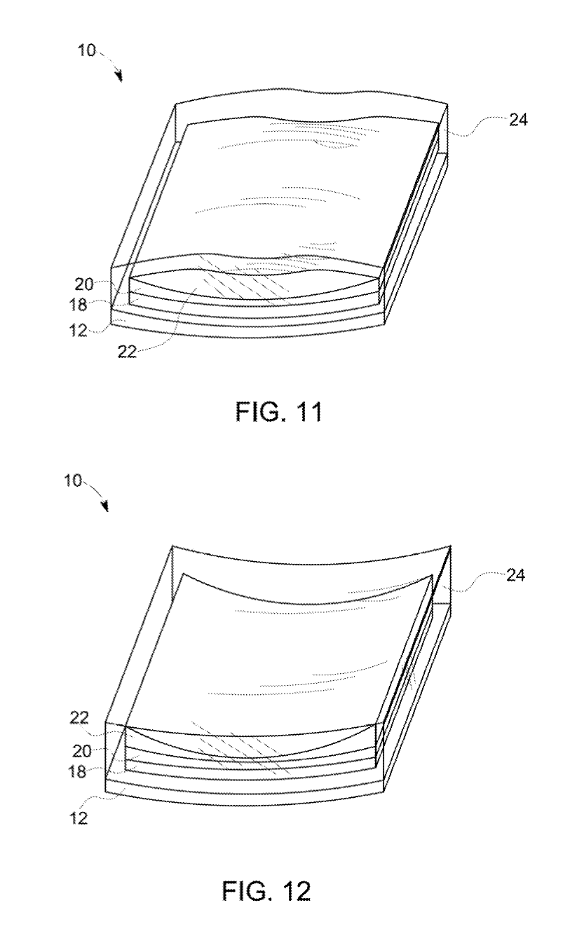

Moreover, an infinite number of different variations of the height profile of cathode material forming the discontinuous cathode layer 22b can be formed as desired to suit the flexibility requirements of the OLED lighting device 10 being made. The thinner depths of the thickness of the cathode material desirably will be located at places where the OLED lighting device 10 must bend in order to satisfy the particular application for which it is being made. When the edges of the OLED lighting device 10 are provided with the thicker depths of cathode material as schematically shown in FIG. 12 for example, the bending can deflect the stresses to the peripheral edges (designated 34 in FIG. 7) where the cathode material has the greatest depth and accordingly is provided with the greatest ability to withstand these stresses. However, as schematically shown in FIG. 11 for example, depositing a cathode 22 with a varying thickness profile so that the peripheral ends (designated 34 in FIG. 8) of the cathode 22 are thinner than the middle of the cathode 22 nonetheless permits bending at the middle (designated 36 in FIG. 8) of the cathode 22 in a manner that compresses toward the middle of the cathode 22 on the concave bending surface.

As schematically shown in FIGS. 3, 4, 11, 12, 13, 14, 15, 16 and 17 for example, a protective cover 24 may be applied over the cathode layer 22 and forms a generally hermetic seal over the underlying layers 20, 18 and 12. In the exemplary method schematically represented in FIG. 19, this step is designated by the square labeled 55. This protective cover 24 is flexible, thermally conductive and at least electrically semi-conductive and desirably electrically conductive. This protective cover 24 desirably may be formed from various suitable materials, including a metalloid (e.g., silicon) or a ceramic (e.g., silicon nitride). In a particular embodiment, the protective cover 24 may incorporate a thermally conductive layer, such as one or more layers of a metal or metal alloy, for example silver, aluminum, tin, copper, steel, and so forth. Alternatively, the protective cover 24 made be formed from a thermally conductive material, such as aluminum nitride.

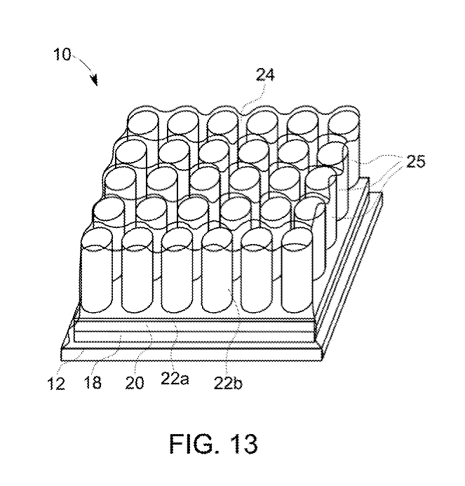

Because some polymers that conventionally are used for the cathode protection layer 24 may not diffuse through spaces measuring one micron across, as schematically shown in FIG. 13 for example, the cathode protection layer 24 applied over the columns 25 or islands 25 of cathode material in the discontinuous cathode layer 22b desirably can take the form of a very thin sheet of a plastic that is laminated to the exposed surfaces of the discontinuous cathode layer 22b and underlying layers 20, 18 and 12 with adhesive. In order to serve as the cathode protection layer 24 of the overall OLED device 10, such thin plastic sheet desirably must be at least electrically semi-conductive and thermally conductive material, and desirably the sheet of material forming the cathode protection layer 24 is electrically conductive.

In addition to the above, the protective cover layer 24 also may include other types of high-strength crystalline polymer fibers, such as polyethylene (DYNEEMA™) and polybenzobisoxazole (ZYLON™), which have a negative coefficient of thermal expansion. These materials actually shrink with increasing temperature, and may be useful in high temperature environments in that they will shrink and provide a more secure protective layer to the underlying cathode 22.

Each of FIGS. 4, 11 and 12 schematically depicts a situation wherein, as the design bending radius 32 (See FIG. 2, but not identified in FIGS. 4, 11 and 12) increases (and thus the bend is less drastic), the cathode layer 22 may have a greater thickness without increasing the likelihood of fracture or delamination of the cathode layer 22. The increase in cathode thickness is, to an extent, desirable in that the cathode layer 22 also serves as a thermally conductive layer and may alleviate the high temperature stresses induced in the OLED device 10. Because of the gaps 27 in the embodiment of the discontinuous cathode layer 22b depicted in FIGS. 3 and 4 for example, the flexibility of the overall OLED device 10 is not impeded by the thickness of the discontinuous cathode layer 22b. And yet the discontinuous cathode layer 22b nonetheless can achieve thicknesses of at least up to ten microns, which are thicknesses of cathode material ample to dissipate the heat generated during operation of the overall OLED device 10. Because of the height variation imposed in the discontinuous cathode layer 22b depicted in FIG. 12 for example, the flexibility of the overall OLED device 10 is not impeded by the relatively thinner thickness of the discontinuous cathode layer 22b at locations (e.g., like region 36 shown in FIG. 7) where bending is desired. And yet the presence of thicknesses of up to ten microns of cathode material at locations (e.g., like region 34 shown in FIG. 7) where bending is not anticipated, provides ample thicknesses of cathode material to dissipate the heat generated during operation of the OLED device.

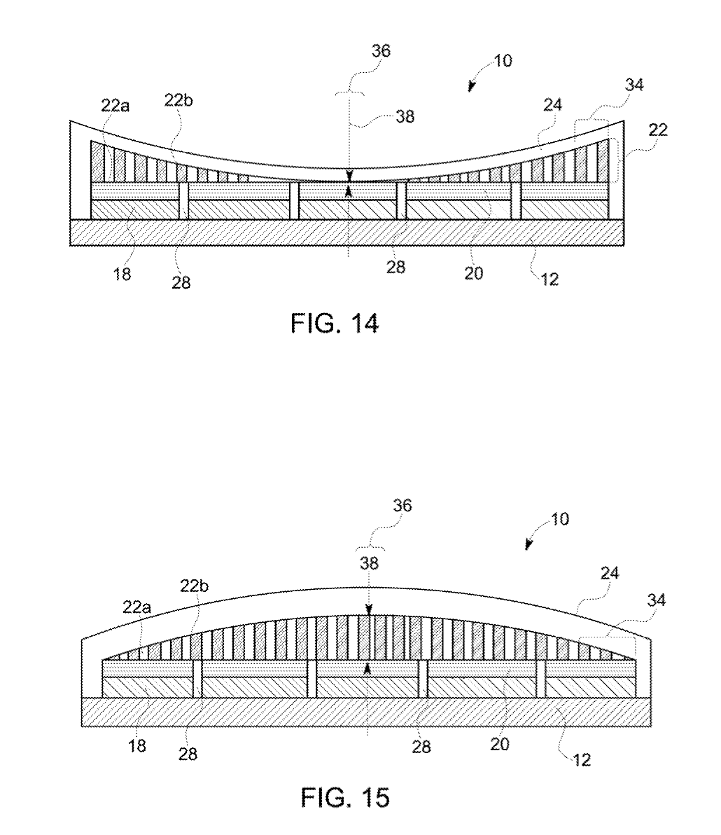

In further alternative exemplary embodiments of the discontinuous cathode layer 22b, the second thickness that defines the discontinuous cathode layer 22b varies as a function of the position of the discontinuous cathode layer 22b on the continuous cathode layer 22a. Accordingly, as schematically shown in FIGS. 14 and 15 for example, in this implementation of the discontinuous cathode layer 22b, the discontinuous cathode layer 22b is rendered discontinuous both by the imposition of varying heights of cathode material forming on the discontinuous cathode layer 22b and by a plurality of gaps 27 separating each column 25 of cathode material from each other column 25 of cathode material. As schematically shown in FIG. 14 for example, the height of cathode material in the discontinuous cathode layer 22b desirably is taller above a plurality of the outer peripheral regions 34 of the discontinuous cathode layer 22b. As schematically shown in FIG. 14 for example, the outer peripheral regions 34 of cathode material that is deposited above a plurality of the outer peripheral regions of the continuous cathode layer 22a desirably measures up to a height of at least ten microns above the first thickness of the continuous cathode layer 22a.

As schematically shown in FIGS. 14 and 16 by the thickness designated 38 for example, the height of cathode material in the discontinuous cathode layer 22b desirably is such that the height of cathode material deposited to form a contiguous region 36 of the discontinuous cathode layer 22b disposed away from the plurality of outer peripheral regions 34 of the discontinuous cathode layer 22b, is up to or less than 200 nanometers. In alternative embodiments schematically shown in FIGS. 15 and 17 for example, the height of cathode material in the outer peripheral regions 34 of the discontinuous cathode layer 22b desirably is shorter than the height of cathode material deposited in the contiguous region 36 of the discontinuous cathode layer 22b disposed distantly from the outer peripheral regions 34 of the discontinuous cathode layer 22b. As schematically shown in FIGS. 14 and 15 for example, the height of a plurality of the columns 25 measures more than twice the first thickness of the continuous cathode layer 22a.

As noted above and schematically shown in FIGS. 3, 14, 15, 16 and 17 for example, the anode 18 and light emitting materials 20 are deposited on the substrate 12. The individual OLED elements 14 shown in FIGS. 1 and 2 are defined by “cutting” through these layers (for example in a laser scribing technique), as indicated by the scribe lines 28. By virtue of the continuous cathode layer 22a, the cathode 22 forms a common electrode layer over the scribed organic material layer 20, and is thus considered a “high work function” layer in that it must be capable of carrying current for all of the OLED elements 14.

As discussed above, it should be appreciated that the present invention also encompasses any manner of flexible OLED lighting device 10 incorporating aspects of the invention as discussed herein.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method for making a flexible, organic electroluminescent device, the method comprising:
forming a continuous anode layer on a portion of the planar upper surface of a flexible substrate;
forming on a portion of the continuous anode layer, an organic layer including one or more organic light emitting materials:
forming a continuous cathode layer on the organic layer, the continuous cathode layer defining a first thickness above the organic layer; and
forming on the continuous cathode layer a discontinuous cathode layer, the discontinuous cathode layer defining a second thickness above the continuous cathode layer, the second thickness varying as a function of its coordinates in a virtual plane parallel to the plane defined by the planar upper surface of the substrate.

2. The method of claim 1, wherein the step of forming the discontinuous cathode layer further comprises:
depositing cathode material through openings defined in at least one mask to form a plurality of columns of cathode material, each column being spaced apart from each other column by a plurality of gaps, the second thickness defining a height of each column above the continuous cathode layer, the height of each column measuring more than twice the first thickness of the continuous cathode layer.

3. The method of claim 2, wherein each of the openings in the mask is spaced apart from the nearest neighboring opening in the mask by a distance of no more than about one micron.

4. The method of claim 2, wherein a height of at least one of the columns of cathode material is at least nine microns.

5. The method of claim 1, wherein the first thickness of the continuous cathode layer is less than or equal to 200 nm.

6. The method of claim 1, wherein the step of forming the discontinuous cathode layer further comprises:
depositing cathode material so that the thickness of the discontinuous cathode layer is not constant and at least one region of the discontinuous cathode layer attains a second thickness of up to nine microns.

7. The method of claim 6, wherein the step of forming the discontinuous cathode layer further comprises:
depositing cathode material so that the second thickness varies as a smoothly varying function of its coordinates in a virtual plane parallel to the plane of the upper surface of the substrate so as to impose a smoothly varying height of cathode material above the continuous cathode layer.

8. The method of claim 7, wherein the step of forming the discontinuous cathode layer further comprises:
depositing cathode material so that the height of the cathode material forming the outer peripheral regions of the discontinuous cathode layer is taller than the height of the cathode material forming the discontinuous cathode layer in regions of the discontinuous cathode layer disposed away from the outer peripheral regions.

9. The method of claim 7, wherein the step of forming the discontinuous cathode layer further comprises:
depositing cathode material so that the height of cathode material is shorter above a plurality of the outer peripheral regions of the continuous cathode layer than the height of the cathode material forming the discontinuous cathode layer in regions of the discontinuous cathode layer disposed away from the outer peripheral regions.

10. The method of claim 1, wherein the step of forming the discontinuous cathode layer further comprises:
depositing cathode material to form a plurality of the outer peripheral regions of the discontinuous cathode layer to a height of at least nine microns above the height of the continuous cathode layer.

11. The method of claim 10, wherein the height of cathode material deposited above a contiguous region of the continuous cathode layer, which contiguous region is disposed away from the plurality of outer peripheral regions of the discontinuous cathode layer and is less than or equal to 200 nanometers.

12. The method of claim 1, further comprising:
forming an encapsulating protective cover over at least the discontinuous cathode layer.

13. The method of claim 12, wherein the step of forming an encapsulating protective cover further comprises:
laminating a very thin sheet of a plastic to the exposed surfaces of the discontinuous cathode layer.

14. A flexible, organic electroluminescent device, comprising:
a flexible planar substrate defining an upper surface;
a continuous anode layer formed on the upper surface of the substrate;
an organic layer including one or more organic light emitting materials formed on the anode layer:
a continuous cathode layer formed on the organic layer, the continuous cathode layer defining a first thickness above the anode layer; and
a discontinuous cathode layer defining a second thickness above the continuous cathode layer, the second thickness varying as a function of the coordinates of the discontinuous cathode layer in a plane parallel to the plane defined by the upper surface of the substrate.

15. The flexible device of claim 14, wherein the first thickness of the continuous cathode layer is in the range of 100 nm to 200 nm.

16. The flexible device of claim 14, wherein the height of cathode material deposited above a plurality of the outer peripheral regions of the continuous cathode layer is at least nine microns above the height of the continuous cathode layer.

17. The flexible device of claim 16, wherein the height of cathode material deposited above a contiguous region of the continuous cathode layer disposed away from the plurality of outer peripheral regions of the continuous cathode layer, is less than or equal to 200 nanometers.

18. The flexible device of claim 14, wherein the discontinuous cathode layer defines a plurality of columns of cathode material formed on the continuous cathode layer, each column being spaced apart from each other column and defining a height above the continuous cathode layer, the height of each column measuring more than twice the first thickness of the continuous cathode layer.

19. The flexible device of claim 18, wherein the height of each column of the plurality of the columns is at least nine microns.

20. The flexible device of claim 18, wherein each column of the plurality of the columns is spaced apart from its nearest neighboring column by a distance of at least one micron.

21. The flexible device of claim 14, wherein the discontinuous cathode layer defines a plurality of columns of cathode material formed on the continuous cathode layer, each column being spaced apart from each other column and defining a height above the continuous cathode layer, the height of a plurality of the columns measuring more than twice the first thickness of the continuous cathode layer.

22. The flexible device of claim 14, wherein the height of cathode material above a plurality of outer peripheral regions of the continuous cathode layer is shorter than the height of cathode material above the regions of the continuous cathode layer disposed away from the plurality of outer peripheral regions of the continuous cathode layer.

23. The flexible device of claim 22, wherein the discontinuous cathode layer defines a plurality of columns of cathode material formed on the continuous cathode layer, each column being spaced apart from each other column and defining a height above the continuous cathode layer, the height of a plurality of the columns measuring more than twice the first thickness of the continuous cathode layer.

24. The flexible device of claim 14, further comprising:
an encapsulating protective cover formed over at least the continuous cathode layer and the discontinuous cathode layer.

25. The flexible device of claim 14, further comprising:
an encapsulating protective cover formed over at least the discontinuous cathode layer, wherein the encapsulating protective cover further comprises a very thin sheet of plastic adhered to less than all of the exposed surfaces of the discontinuous cathode layer.

26. A flexible, organic electroluminescent device made by the process comprising:
forming a continuous anode layer on a portion of the planar upper surface of a flexible substrate;
forming on a portion of the continuous anode layer, an organic layer including one or more organic light emitting materials;
forming a continuous cathode layer on the organic layer, the continuous cathode layer defining a first thickness above the organic layer; and
forming on the continuous cathode layer a discontinuous cathode layer, the discontinuous cathode layer defining a second thickness above the continuous cathode layer, the second thickness varying as a function of its coordinates in a virtual plane parallel to the plane defined by the planar upper surface of the substrate.
